(19) United States
(12) Patent Application Publication
(10) Pub. No.: US 2026/0123479 A1
(43) Pub. Date: Apr. 30, 2026

(54) SUBSTRATE ARCHITECTURE AND ELECTRONIC DEVICE RELATED THERETO

(71) Applicant: PanelSemi Corporation, New Taipei City (TW)

(72) Inventor: Chin-Tang LI, New Taipei City (TW)

(21) Appl. No.: 19/370,368

(22) Filed: Oct. 27, 2025

Related U.S. Application Data
(60) Provisional application No. 63/711,873, filed on Oct. 25, 2024.

(51) Int. Cl. H01L 23/498; H01L 23/15

(52) U.S. Cl. CPC H10W 70/635; H10W 70/65; H10W 70/692; H10W 90/701

(57) ABSTRACT

A substrate architecture includes a substrate, a film-layered structure, and a plurality of conductive components. The substrate defines a plurality of through-holes; each of the through-holes is defined with a reception accommodation and an inner surface designating the reception accommodation. The film-layered structure at least partially encloses an opening of the corresponding one of the through-holes located at a surface of the substrate; the film-layered structure defines a conductive face facing the opening, and where the conductive face corresponding with the opening is at least partially conductive. The conductive components are respectively arranged in the reception accommodations of the through-holes, at least partially contacting the inner surfaces of the corresponding through-holes, and electrically connected to the film-layered structure. In a direction parallel with a horizontal plane of the substrate, one of the conductive components has a cross-sectional profile characterized by a homogeneous medium.

### CROSS REFERENCE TO RELATED APPLICATIONS

This Non-provisional application claims priority to U.S. provisional patent application with Ser. No. 63/711,873 filed on Oct. 25, 2024. This and all other extrinsic materials discussed herein are incorporated by reference in their entirety.

### BACKGROUND

### Technology Field

The present invention relates to a substrate with a through-hole structure, applicable in semiconductor packaging, printed circuit boards, or other electronic component fields, particularly concerning a substrate architecture, manufacturing method thereof, and electronic device related thereto.

### Background

As electronic products trend towards miniaturization, high performance, and high integration, substrate architectures play an increasingly crucial role in electronic packaging. However, traditional substrate through-hole structures often encounter multiple challenges, including poor conductivity and inferior high-frequency performance. Notably, reliability issues are of particular concern, primarily resulting from the difference in coefficient of thermal expansion (CTE) between substrate materials and metallic materials. This difference causes stress concentration in specific areas of the substrate during the period of temperature changing, potentially leading to substrate warpage or even localized fractures, ultimately to be risky of product functional failure. The combined impact of these issues makes it difficult for traditional structures to simultaneously meet various performance requirements. Therefore, developing a substrate through-hole structure that can reduce thermal stress risks while at least keeping overall performance in terms of miniaturization, high integration, conductivity, and high-frequency demands has become a focal point of research in the current electronic packaging field.

### SUMMARY

This invention provides a substrate architecture which comprises a substrate having a plurality of through-holes and a film-layered structure arranged at one lateral of the substrate. The substrate architecture of this invention has batter reliability.

The substrate architecture of this invention comprises a substrate, a film-layered structure, and a plurality of conductive components. The substrate defines a first surface, a second surface opposite to the first surface, and a plurality of through-holes. Each of the through-holes comprises an accommodation space, an inner surface delineates the accommodation space, and two openings respectively arranged on the first surface and the second surface. The film-layered structure is arranged on at least one of the first surface or the second surface of the substrate. The film-layered structure covers at least a partial part of an opening of a corresponding one of the through-holes at a surface of the substrate. The film-layered structure defines a conductive surface facing the opening of the through-hole, and the conductive surface corresponding to the opening of the conductive face is at least partially conductive. The plurality of conductive components is respectively arranged in the accommodations space of the through-holes. At least partial part of the conductive components contact the inner surfaces of the corresponding ones of the through-holes and electrically connected to the conductive surface of the film-layered structure. At least one of the conductive components defines a cross-sectional profile of a homogeneous medium in a direction along a horizontal plane of the substrate.

In one embodiment, the substrate comprises at least one of a glass material, a ceramic material, or a glass-ceramic material.

In one embodiment, the substrate is a single-layer substrate.

In one embodiment, the substrate is a multi-layer substrate, and at least one layer of the multi-layer substrate comprises an organic material, and layer comprising the organic material defines a thickness less than 100 μm.

In one embodiment, the substrate is a multi-layer substrate and each layer of the multi-layer substrate defines a thickness less than 100 μm.

In one embodiment, the substrate is a multi-layer substrate, and at least one layer of the multi-layer substrate comprises polyimide material.

In one embodiment, the substrate defines a coefficient of thermal expansion (CTE) along the horizontal plane of the substrate, and the CTE of the substrate is no greater than 10 ppm/° C.

In one embodiment, the through-hole defines a hole diameter, the substrate defines a substrate thickness, and the ratio of the substrate thickness to the hole diameter is no less than 1; wherein the hole diameter of the through hole is a maximum hole diameter, and the substrate thickness is a maximum substrate thickness.

In one embodiment, the hole diameter of the through hole is no greater than 100 μm.

In one embodiment, the substrate thickness is no greater than 300 μm.

In one embodiment, the substrate thickness is no greater than 500 μm.

In one embodiment, the filmed-layered structure comprises a conductive structure.

In one embodiment, the filmed-layered structure comprises a conductive structure and an adhesive layer, the adhesive layer bonds the conductive structure and the substrate.

In one embodiment, the conductive structure is a single layer non-patterned conductive layer, or a single-layer copper foil, an electroless plated copper layer, a sputtered copper layer, or an evaporated copper layer.

In one embodiment, the conductive structure comprises a single-layer patterned conductive layer or a multi-layer patterned conductive layer, and the patterned conductive layer comprises copper material.

In one embodiment, the conductive component contacts at least partial part of the inner surface of the corresponding through-hole by non-chemical bonding.

In one embodiment, the conductive component is a single conductive-material member.

In one embodiment, the conductive component comprises copper material.

In one embodiment, the conductive component is a deposited conductive-material member.

In one embodiment, the conductive components is formed in the corresponding through-hole by an electroplating process utilizing the conductive face of the film-layered structure.

In one embodiment, the through-hole defines a accommodation volume of the accommodation space, the conductive components arranged in the accommodation space of the corresponding through-hole defines an filling volume; the filling volume is not less than 90% of the accommodation volume.

In one embodiment, the substrate architecture further includes an insulating component, the insulating component includes at least an insulating material arranged between a hole wall of the corresponding one of the through-holes and the conductive component arranged therein; the insulating material delineates the inner surface of the through-hole, or the insulating material and the hole wall jointly delineate the inner surface of the through-hole.

In one embodiment, the insulating component comprises an insulating layer arranged at least partial of the surface of the substrate opposite to film-layered structure.

In one embodiment, the conductive component comprises an outer surface which defines a surface roughness no greater than 0.6 μm, or no greater than 0.3 μm.

In one embodiment, the surface roughness of the outer surface of the conductive component is a maximum surface roughness or a Root Mean Square (RMS) roughness (Rq).

In one embodiment, the substrate architecture further comprises a second film-layered structure arranged on another surface of the substrate opposite to the film-layered structure, the second film-layered structure covers at least partial of the corresponding opening at the other surface of the substrate and electrically connects to the corresponding conductive component.

In one embodiment, the second film-layered structure comprises a conductive structure, and the conductive structure can be a single-layer non-patterned conductive layer, a single-layer patterned conductive layer, a multi-layer patterned conductive layer, a single-layer copper foil, an electroless plated copper layer, a sputtered copper layer, or an evaporated copper layer.

In one embodiment, the patterned conductive layer of the second film-layered structure comprises copper material.

In one embodiment, the insulating component comprises an insulating layer covers at least partial of the surface of the substrate opposite to the film-layered structure, and the insulating layer is arranged between the second film-layered structure and the surface of the substrate opposite to the film-layered structure.

In one embodiment, the through-hole is formed by a laser processing.

In one embodiment, the substrate architecture comprises an external conductive component arranged at one side of the substrate opposite to the film-layered structure and electrically connected to the conductive component.

This invention also provides an electronic devices, which comprises the abovementioned substrate architecture, a plurality of external conductive components, and a plurality of electrical components. The external conductive components electrically connected to the film-layered structure of the substrate architecture, the film-layered structure of the substrate architecture is arranged between the external conductive components and the conductive components of the substrate architecture and electrically connected to the conductive components. The electrical components are electrically connected to external conductive components.

In one embodiment, one of the electronic components is arranged between the substrate architecture and another one of the electronic components.

In one embodiment, one of the electronic components is arranged between adjacent two of the electronic components.

In one embodiment, at least one of the electronic components is an integrated passive device (IPD) or a light emitting diode (LED).

The invention also provide a manufacturing method of the abovementioned substrate architecture, comprises: providing a substrate assembly, the substrate assembly includes a substrate and a film-layered structure. The substrate comprises a plurality through-holes, and the film-layered structure covers openings of the plurality through-holes; and depositing a conductive material to form a conductive component in the corresponding one of the through-holes, in which the conductive components are electrically connected to the film-layered structure. One of the conductive components has a cross-sectional profile of a homogeneous medium in a direction along a horizontal plane of the substrate.

Detailly, the substrate of the substrate assembly comprises a first surface, a second surface opposite to the first surface, and a plurality of through-holes. Each of the through-holes comprises an accommodation space, an inner surface delineates the accommodation space, and two openings respectively arranged on the first surface and the second surface. The film-layered structure is arranged on at least one of the first surface or the second surface of the substrate. The film-layered structure covers at least partial part of an opening of a corresponding one of the through-holes at a surface of the substrate. The film-layered structure defines a conductive surface facing the opening of the through-hole, and the conductive surface corresponding to the opening of the conductive face is at least partially conductive. The plurality of conductive components are respectively arranged in the accommodations space of the through-holes. At least partial part of the conductive components contact the inner surfaces of the corresponding ones of the through-holes.

In one embodiment, in the step of providing the substrate assembly, the substrate with the through-holes is provided, and the film-layered structure is arranged to one of the first surface or the second surface of the substrate, and the film-layered structure covers at least partial part of the opening of the corresponding through-hole.

In one embodiment, in the step of providing the substrate assembly, an undefined substrate is provided, and the film-layered structure is arranged to one surface of the undefined substrate, and a plurality of through-holes are formed in the undefined substrate to provide the substrate; and a surface of the film-layered structure is exposed by openings of the through-holes.

In one embodiment, the film-layered structure comprises a single-layer patterned conductive layer or a multi-layer patterned conductive layer, and the surface having the patterned layer of the film-layered structure and the substrate approach to each other, wherein the patterned conductive layer can be an adhesive layer.

In one embodiment, the substrate assembly further includes a carrier substrate arranged at one side of the film-layered structure opposite to the substrate, and the carrier substrate is removed before or after the step depositing the conductive material.

In one embodiment, the through-holes are formed by laser processing.

In one embodiment, the conductive component contact to at least partial part of the inner surface of the through-hole by non-chemical bonding.

In one embodiment, in the step of depositing the conductive material, comprises electrically connecting the conductive surface of the film-layered structure to a process electrode, and depositing the conductive material in the corresponding through-hole to the conductive surface of the film-layered structure by an electroplating process therebetween to form the conductive component.

In one embodiment, in or after the step of depositing the conductive material, a patterned conductive layer is formed on the second surface of the substrate in which the patterned conductive layer covers at least partial part of the opening of the corresponding through-hole and electrically connects to the conductive component.

In one embodiment, a removing step is performed after the step of depositing the conductive material and forming the conductive component, to remove a protrusion portion of the conductive component which is protruded out of the substrate.

In one embodiment, the manufacturing method further comprises a step of arranging an insulating material between the through-hole and the conductive component; the insulating material is arranged at least a partial part of the hole wall of the through hole, and the insulating material delineates the inner surface of the through-hole.

In one embodiment, the manufacturing method further comprises a step of arranging an insulating material, comprises: filling an insulating material into the corresponding one of the through-holes before forming the conductive component, and forming an inner hole in the insulating material, wherein the inner hole of the insulating material delineates the inner surface of the through-hole.

In one embodiment, a step of polishing is performed after the step of arranging the insulating material or forming the inner hole, comprises polishing the inner surface delineated by the insulating material or jointly by the insulating material and the hole wall of the through-hole.

In one embodiment, further arranging an insulating layer on at least partial of one surface of the substrate, the insulating layer covers at least partial part of the opening of the corresponding through-hole.

In one embodiment, after forming the insulating layer, the insulating layer is polished.

In one embodiment, after forming the insulating layer, a plurality of windows is formed in the insulating layer in which the plurality of windows correspond to the through-holes.

In one embodiment, the conductive layer is a copper seed layer.

In one embodiment, a plurality of external conductive components is further arranged at one side of the substrate opposite to the film-layered structure, and the external conductive components electrically connect to the corresponding conductive components.

In one embodiment, a second film-layered structure is further arranged at one side of the substrate opposite to the film-layered structure; the second film-layered structure comprises a conductive structure, and the conductive structure is a single-layer non-patterned conductive layer, or a single-layer or a multi-layer patterned conductive layer.

In one embodiment, a plurality of external conductive components is arrange at one side of the film-layered structure opposite to the substrate.

Accordingly, the substrate architecture of the this invention comprises a plurality of through-holes and a plurality of conductive components respectively arranged in the through-holes, which increases the flexibility of arranging electronic comment on the substrate architecture. In addition, the non-chemical bonding between the conductive component and the hole wall prevents damage to the substrate architecture due to changes in the volume of the conductive component and the substrate caused by temperature changes during various processes, thereby improving the reliability of the substrate structure.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a sectional side view of the substrate architecture in this invention;

FIG. 1B is a top view showing the through-hole of the substrate architecture in this invention;

FIG. 1C and FIG. 1D are top views showing the film-layered structure of the substrate architecture in this invention;

FIG. 2A to FIG. 2D are section side views showing embodiments of the substrate architecture in this invention;

FIG. 3A to FIG. 3C are schematic diagrams showing embodiments of the substrate architecture with the second film-layered structure in this invention;

FIG. 3D to FIG. 3E are top views showing the through-holes with the insulating material of the substrate architecture in this invention;

FIG. 4A to FIG. 4C are schematic diagrams showing embodiments of the substrate architecture with the insulating layer in this invention;

FIG. 5A and FIG. 5B are schematic diagrams showing the substrate architecture with the external conductive components at one side in this invention;

FIG. 6A and FIG. 6B are schematic diagrams showing the substrate architecture with the external conductive components at two sides in this invention;

FIG. 7A to FIG. 7C are schematic diagrams showing embodiments of the substrate architecture with electronic components in this invention;

FIG. 8A to FIG. 8F are schematic diagrams showing a process for manufacturing the substrate architecture in this invention;

FIG. 9A to FIG. 9F are schematic diagrams showing another process for manufacturing the substrate architecture in this invention;

FIG. 10A to FIG. 10D are schematic diagrams showing another process for manufacturing the substrate architecture in this invention;

FIG. 11A and FIG. 11B are schematic diagrams showing the relevant positions between the substrate and the film-layered structure in this invention;

FIG. 12A to FIG. 12C are schematic diagrams showing a process of arranging the insulating material on the hole wall of the through-holes of the substrate architecture in this invention; and

FIG. 13A to FIG. 13C are schematic diagrams showing a process of arranging the insulating layer and the second film-layered structure of the substrate architecture in this invention.

### DETAILED DESCRIPTION OF THE DISCLOSURE

The disclosure will become more fully understood from the detailed description and accompanying drawings, which are given for illustration only, and thus are not limitative of the present disclosure.

The following description will refer to relevant drawings to explain the substrate architecture according to the preferred embodiments of this invention, wherein the same elements will be described using the same reference symbols.

The advantages, features, and methods of realizing this invention will be clearly explained in the following embodiments with reference to the drawings. However, this invention can be embodied in many different forms and should not be construed as limited to the embodiments described below. On the contrary, these embodiments are provided to make this specification clear and complete, and to fully convey the scope of the invention to those skilled in the art. The invention should be defined only by the scope of the patent claims. Therefore, in the embodiments, well-known constituent elements, operations, and techniques are not described in detail to avoid obscuring the technical features of the invention. Throughout the specification, the same or similar elements are represented by the same or similar element symbols. Throughout the specification, when an element is said to be “connected” to another element, it can be “directly or indirectly mechanically connected” to another element, or “electrically connected” to another element, and one or more intermediate elements are allowed to be inserted between them. It is further understood that in this specification, the terms “include” and/or “comprise” specify the stated features, integers, steps, operations, elements and/or components, but do not exclude the presence or addition of one or more other features, integers, steps, operations, elements and/or components, or combinations thereof. Unless otherwise defined, all terms used in this specification (including technical and scientific terms) have the same meanings as commonly understood by those skilled in the field to which this invention belongs. It is further understood that terms, such as those defined in commonly used dictionaries, should be interpreted as having meanings consistent with their meaning in the context of the relevant art and will not be interpreted in an idealized or overly formal sense unless expressly so defined in this specification.

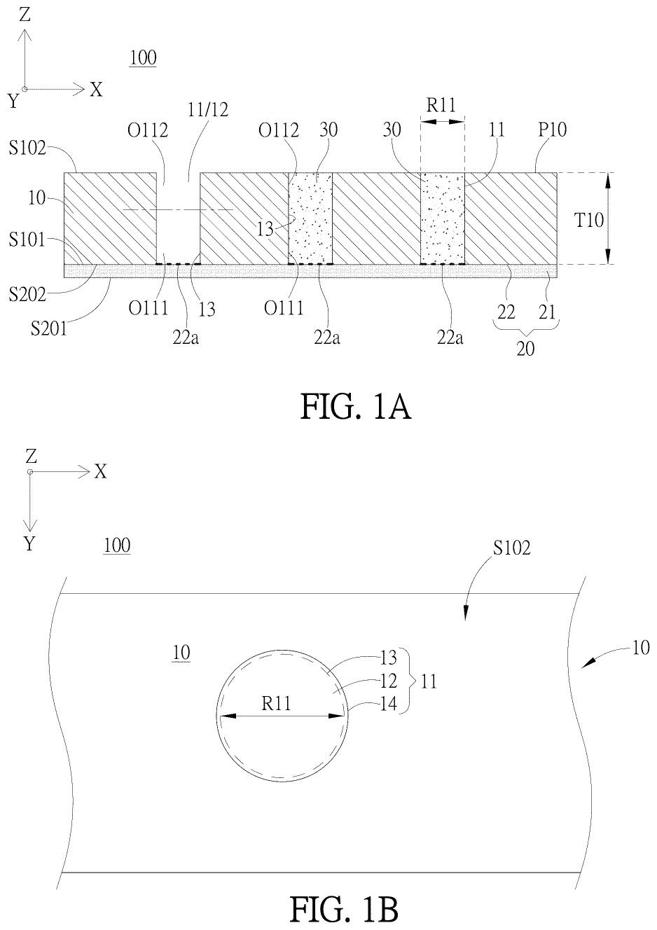

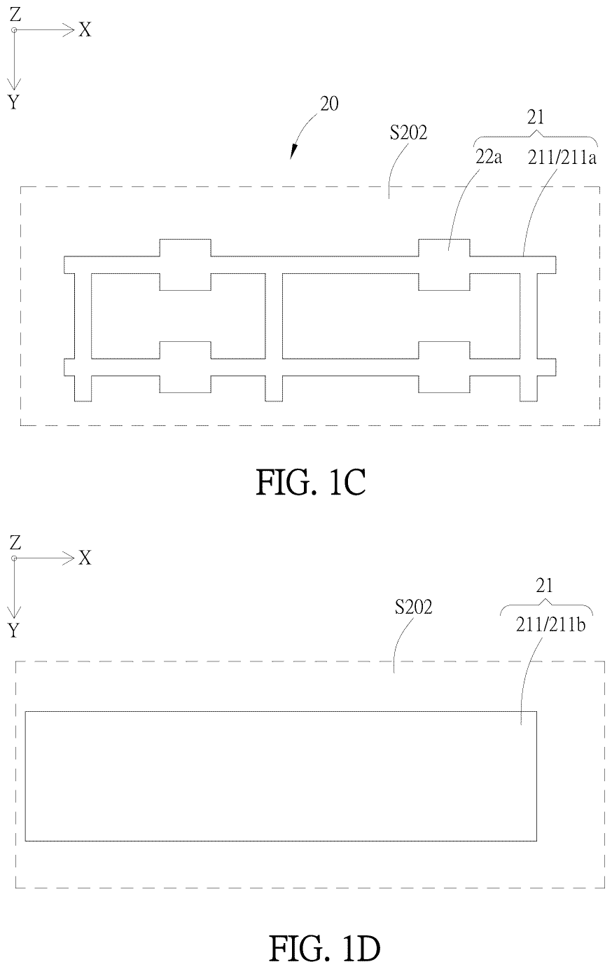

Referring to FIG. 1A, shows an embodiment of the substrate architecture in this invention. The substrate architecture 100A includes a substrate 10, a film-layered structure 20, and a plurality of conductive components 30. The substrate 10 defines a first surface S101, a second surface S102, and a plurality of through-holes 11; each of the through-holes 11 defines an accommodation space 12, an inner surface 13 delineates the accommodation space 12, and two openings O111, O1112 respectively arranged on the first surface S101 and the second surface S102. The film-layered structure 20 covers at least a partial part of an opening(s) O111 of the corresponding one or ones of the through-holes 11 on the first surface S101 of the substrate 10. The film-layered structure 20 comprises a conductive structure 21 and a conductive surface 22. The conductive surface 22 is the surface of the film-layered structure 20 facing the substrate, and where the conductive surface 22 corresponding to the opening(s) O111 is at least partially conductive. The conductive surface 22 can further completely enclose the corresponding opening(s) O111 on the first surface S101 of the substrate 10, and the conductive surface 22 facing to the corresponding opening(s) O111, especially at least a partial part of conductive surface 22 exposed by the opening(s) O111 is(are) conductive. In some cases, the conductive surface 22 defines a plurality of area units 22a exposed by the corresponding one(s) of the opening(s) O111, and the area units 22a are at least partially conductive.

The conductive components 30 are respectively arranged in the accommodations space 12 of the corresponding ones of the through-holes 11, and at least a partial part of the conductive component 30 contacts the inner surfaces 13 of the corresponding through-hole 11, and the conductive component 30 is electrically connected to the conductive surface 22 of the film-layered structure 20. At least one of the conductive components 30 has a cross-sectional profile of homogeneous medium (material) in a direction along a horizontal plane P10 of the first surface S101 or the second surface 102 of the substrate 10. In FIG. 1A, the horizontal plane P10 of the substrate 10 is a surface extending jointly in a first horizontal direction X and a second horizontal direction Y of the substrate 10.

In one or some embodiments, one or ones of the conductive component(s) has the cross-sectional profile of homogeneous medium in the direction along the horizontal plane P10 of the substrate 10, and the conductive component 30 is arranged in the corresponding one of the through holes 11, it can also be said that one or ones of the conductive components 30 have a cross-sectional profile of homogeneous medium in a radial direction of the through-hole 11. In addition, the description of “homogeneous medium” here refers to the conductive component(s) 30 is (are) formed by a same material in the cross-section, and there is no interface between the same material, the “interface” here can be an interface formed due to different manufacturing process. Furthermore, the description of “at least a partial part of the conductive component 30 contacts the inner surface 13 of the through-hole 11” includes a status of a partial part of the conductive component 30 contacts to the inner surface 13 of the through-hole 11, and a status of an outer surface of the conductive component 30 completely contacts to the inner surface 13 of the through-hole 11. Therefore, the manufacturing method of the conductive components 30 in this invention rule out the process that the conductive member 30 is in full contact with the inner surface of the through-hole 11.

Since there is no requirement for complete contact between the conductive component 30 and the inner surface 13 of the through-hole, these conductive members 30 can move or adjust positions thereof relative to the substrate 10 freely during thermal expansion and contraction. It indicated that the conductive component 30 can be easily peeled off, removed, or separated from the inner surface 13 of the through-hole 11 due to minor external forces, thereby preventing stress accumulation upon the substrate 10 and reducing potential risks of substrate deformation, micro-cracking, damage, warpage, material fatigue, or the like. The said minor external forces include, but are not limited to, stress formed by the difference in coefficient of thermal expansion (CTE) between the substrate 10 and the conductive component 30, especially during thermal shock. The film-layered structure 20 defines two opposite surfaces S201 and S202 and faces to the substrate 10 by one surface. In this embodiment, the surface S202 is the conductive surface 22 and is the surface facing the substrate 10. FIG. 1B is a top view of the substrate architecture 100A, the through-hole 11 of the substrate 10 further defines a hole wall 14; in a status which there is no other material arranged or filled in the through-hole 11, the hole wall 14 is equivalent to the inner surface 13 of the through-hole 11. In the case that the accommodation space 12 of the through-hole 11 is provided with other material such as an insulating material, the hole wall 14 and the inner surface 13 of the through-hole 11 are different surfaces.

In some embodiments, the substrate 10 defines a coefficient of thermal expansion along the horizontal plane P10 no greater than 10 ppm/° C.; the coefficient of thermal expansion of the substrate 10 can be a synergistic coefficient of thermal expansion of the substrate 10. The substrate 10 can be an inorganic substrate; for example, the substrate 10 can be glass and/or ceramic materials, such as glass substrate, ceramic substrate, or glass-ceramic substrate, or comprises glass material, ceramic material, or both. The substrate 10 can also be an organic substrate, such as a polyimide (PI) substrate, a PET (polyethylene terephthalate) substrate, a PEN (polyethylene naphthalate) substrate, a LCP (liquid crystal polymer) substrate, a PDMS (polydimethylsiloxane) substrate, or comprises PI materials, PET materials, PEN materials, LCD materials, or PDMS materials. The substrate 10 can be a rigid substrate or a resilient substrate, or includes a flexible substrate. The substrate 10 also can be a single-layer substrate or a multi-layer substrate; if the substrate 10 is a multi-layer substrate, at least one layer can include organic material. In this specification, the distinct difference between single-layer and multi-layer substrates is the layers in the multi-layer substrates can be separated. A single-layer substrate does not only include a substrate made of a single material, a single-lay substrate can be a substrate made from or made of a composite with mixed materials with a single-layer structure. The multi-layer substrate can be a substrate comprising a plurality of separable layer which are made of or made from same or different materials. At least one layer of the multi-layer substrate can include PI material or the materials of the abovementioned organic substrate. In some cases, at least one layer of the multi-layer substrate can define a layer thickness no greater than 100 μm, or each layer can define a layer thickness no greater than 100 μm. In some cases, at least one layer or each layer of the multi-layer substrate defines a coefficient of thermal expansion no greater than 10 ppm/° C. along the horizontal plane of the substrate 10.

Referring to FIG. 1A and FIG. 1B, in some embodiments, the substrate 10 defines a thickness T10, and at least one of the through-holes 11 can define a hole diameter R11. The ratio of thickness T10 to hole diameter R11, that is the aspect ratio of the through-hole 11, is no less than 1, 2, 3, 5, 10, or not less than 16. The diameter R11 of the through-hole 11 in this case refers to the maximum diameter thereof, and the thickness T10 of the substrate 10 is the maximum thickness, but not limited thereto. In some embodiments, the diameter R11 is no greater than 100 μm or no greater than 60 μm, and the thickness T10 is no greater than 500 μm or no greater than 300 μm, but not limited thereto.

Referring to FIG. 1C and FIG. 1D, are top views of the film-layered structure 20 of the invention. In some embodiments, the film-layered structure 20 include a conductive 21, a conductive surface 22 and other related structures. The conductive structure 21 can include one or ones of conductive layers 211. When the conductive layer 211 is a single layer, it can be a-patterned conductive layer 211a if a non-patterned conductive layer 211b. In one embodiment, the conductive layer 22 is a multi-layer conductive layer, preferably, the conductive layers 211 are patterned conductive layers 211a, with at least two patterned conductive layers 211a are electrically connected to each other, and these patterned conductive layers 211a are arranged and combined with an insulating material 212, which forms, for example but not limited to, a structure like a redistribution layer (RDL). In FIG. 1C, the conductive structure 21 can include a plurality of area units 22a, and the area units 22a are electrically connected to the conductive layer 211.

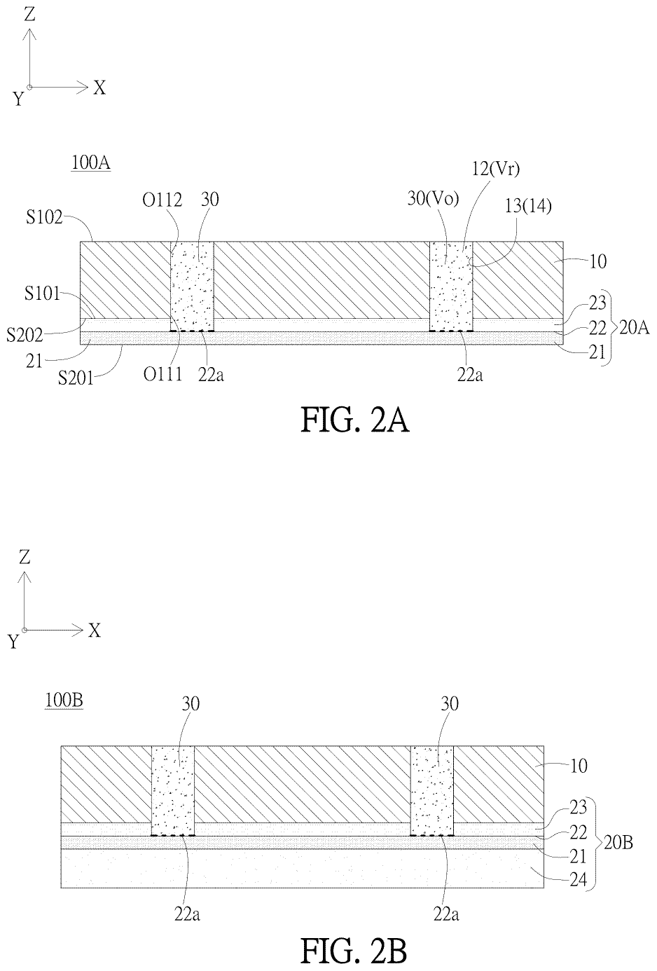

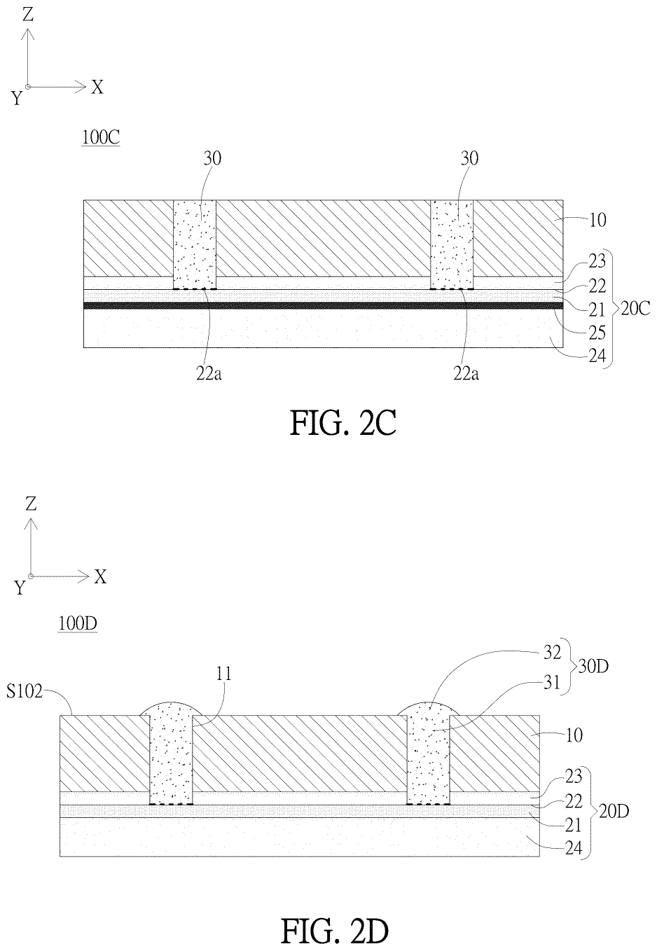

Please refer to FIG. 2A, the film-layered structure 20A of the substrate architecture 100A may further include an adhesive layer 23 between the conductive structure 21 and the substrate 10 to bond the aforementioned two. In this embodiment, the surface S202 of the film-layered structure 20A is a surface that the adhesive layer 23 facing the substrate 10. The conductive components 30 can be protrude from the surface S101 of the substrate 10, pass through the adhesive layer 23, and electrically connect to the conductive surface 22 of the film-layered structure 20A. In this embodiment, surface S202 of the film-layered structure 20A and the conductive surface 22 are not the same surface.

In one embodiment, the methods for arranging the conductive layer 211 on substrate 10 may include vacuum sputtering, vacuum evaporation, magnetron sputtering, electroplating, electroless plating, lamination or cladding, thermal compression, chemical vapor deposition (CVD), printing technologies, ion beam assisted deposition (IBAD), and other technical means the like.

The abovementioned technical approaches, such as electroplating, electroless plating, sputtering, lamination, or thermal compression, may derive or form an intermediate functional layer, including but not limited to a reaction layer or a diffusion layer, which can be equivalent to the adhesive layer 23. For example, when the conductive layer is arranged by a thermal cladding process and the substrate is an organic substrates, such as resin substrates, the intermediate layer can be the result of reactions between oxides of copper material and resin functional groups of resin which mainly comprises Cu—O—C bonding. In another embodiment, the organic substrate is a PI substrate, the intermediate layer can be the result of reactions between imide rings and copper, which mainly comprises Cu—O—C and Cu—N bondings. In these cases, the electrical resistance of the intermediate layer falls between the conductors (conductive layer) and insulators (substrate). For inorganic substrates, such as glass or ceramic substrates, which has less functional groups, so the intermediate layer can form Cu—O—Si bonding or Cu—O—Al bonding, with a electrical resistance closer to that of insulators (substrate).

Referring to FIG. 2B, in the substrate architecture 100B, the conductive structure or the conductive layer 211 can be implemented on a carrier 24 first, in which the carrier 24 can be or a non-conductive substrate or a conductive substrate, and the conductive substrate can include the adhesion layer 23. After completing the conductive structure 21 or the conductive layer 211, an adhesive material or an adhesive layer 23 is arranged on one side of the conductive structure 21 or the conductive layer 211 thereof opposite to the carrier 24. The adhesive materials include, but are not limited to, epoxy, acrylic, polyimide, etc. Here, the adhesive material can be non-layered adhesive material or adhesive material without specific form, and this can also be considered as an expanded embodiment of the film-layered structure 20B. After the adhesive material or the adhesive layer is arranged, approaching and bonding the film-layered structure 20B to the substrate 10 by the surface with the adhesive layer 23, then the carrier 24 is removed. In some cases, the carrier 24 may not be removed for subsequent processes. In addition, the adhesive layer 23 can also be arranged on the substrate 10 for bonding to the film-layered structure 20B.

The materials of the conductive layer 211 include but are not limited to elemental materials, alloys, chemical compounds, conductive polymers, or composites. The elemental materials comprises copper (Cu), aluminum (Al), silver (Ag), gold (Au), nickel (Ni), tin (Sn), or Graphene, the conductive polymers include such as but not limited to polyaniline (PANI) or polypyrrole (PPy), or composite materials comprises but not limited to carbon nanotubes (CNT) or functional carbon nanotubes doped with other metal particles. In addition, the non-patterned conductive layer mentioned above refers to a continuous conductive layer without design, including but not limited to copper foil and copper plating layer (include but not limited to an electroless plated copper layer, a sputtered copper layer, or an evaporated copper layer). The patterned conductive layer includes a conductive layer with designs (ex. a circuitry), which comprises or not comprises reproducible designs. Referring to FIG. 2C, the film-layered structure 20C of the substrate architecture 100B further includes a release layer 25 between the carrier 24 and conductive structure 21. By providing light exposure or temperature changes to the release layer 25, the carrier 24 can be easily removed from the conductive structure 21 in the subsequent processes.

Since each conductive component 30 is made of the same material and has no interfaces, which means that the conductive component 30 can is a single conductive material member. In this invention, the manufacturing process of the conductive components 30 includes but not limited to plating, ex. electroplating, the surface having conductivity of the film-layered structure 20. In this process, the area having conductivity on the conductive surface 22 of the film-layered structure 20 is used as cathode for an electroplating process, and the conductive material may gradually deposit on the area having conductivity of the film-layered structure 20, and forming the conductive components 30 in the accommodation space 12 of a corresponding one of the through-holes 11, therefore the conductive components 30 can also be considered as a deposited conductive material member. The process for deposition conductive material also include technical means such as vacuum sputtering, vacuum evaporation, magnetron sputtering, electroless plating, chemical vapor deposition, ion beam assisted deposition. Additionally, at least a partial part of the conductive members 30 may contact the inner surface 13 of the corresponding one of the through-holes 11 by non-chemical bonding. The-chemical bonding in this specification is not limited to bonding between metallic or non-metallic materials, but broadly refers to attraction forces between atomics, which comprises: the ionic bonding, the covalent bonding, the metallic bonding, the hydrogen bonding, the Van der Waals Forces. Therefore, the wording “non-chemical bonding” itself means the force at least excluding the types of chemical bonds listed above. Although these conductive components 30 contact their corresponding inner surfaces 13 by non-chemical bonding, other forces still be existed therebetween, such as mechanical contact force, static friction, gravitational force, weak electrostatic attraction; most of these forces are reversible, or the conductive component 30 and its corresponding inner wall 13 are separable. Due to the absence of chemical bonding between the conductive components 30 and the inner wall 13 of the through-hole 11, these conductive components 30 can be moved or adjusted their position freely relative to substrate 10 during thermal expansion and contraction. For example, when the substrate architecture is heated due to processing requirements, and the volume of the substrate 10 and the conductive components 30 changes, the conductive components 30 can freely adjust its position relative to the substrate 10.

The materials of conductive member 30 include, but are not limited to, copper (Cu), aluminum (Al) silver (Ag), gold (Au), nickel (Ni), tin (Sn).

In some embodiments, an outer surface of the conductive component 30 defines a surface roughness that is no greater than 0.6 μm, or no greater than 0.3 μm. This surface roughness of the conductive component has its corresponding signal frequencies, which can be referred to the IPC-4562A standard, but is not limited thereto it. Moreover, this surface roughness can be either an average surface roughness or a maximum surface roughness. The calculation methods for surface roughness include but are not limited to: Root Mean Square Roughness (Rrms or Rq), Arithmetic Mean Roughness (Ra), Peak Count Roughness (Rpc), Mean Spacing of Profile Irregularities Roughness (Rs), Mean Spacing of Profile Elements Roughness (Rsm), or the like. A lower surface roughness can reduce transmission loss of high-frequency signals, thereby improving the conductivity performance of the conductive component. Therefore, the loss of the high-frequency signals during transmission is reduced since the conductive component 30 has a lower surface roughness. However, the signals can be transmitted by other transmission paths (such as the hole wall 14 of through-hole 11), but high-frequency signals is naturally transmitted by the outer surface of the conductive components 30 with lower surface roughness to reduce loss of the signal.

In some embodiments, referring to FIG. 2A, the accommodation space 12 defines an accommodation volume Vr, and the conductive component 30 within the accommodation space 12 of its corresponding through-hole 11 defines an filling volume Vo. The filling volume Vo. is no less than 90% of the accommodation volume Vr.

In some embodiments, referring to FIG. 2D, the conductive member 30D of the substrate architecture 100D includes a conductive segment 31 arranged within the through-hole 11 and electrically connected to the film-layered structure 20D, and a conductive protrusion 32 electrically connected to the conductive segment 31 and exposed out of the surface S102 of the substrate 10. The conductive member 30D with the conductive protrusion 32 can be an intermediate product during the manufacturing process and can be a final product as well. If the conductive member 30FD with the conductive protrusion 32 is an intermediate product, the conductive protrusion 32 can be removed by grinding or laser processing, but not limited thereto, to expose the conductive segment 31.

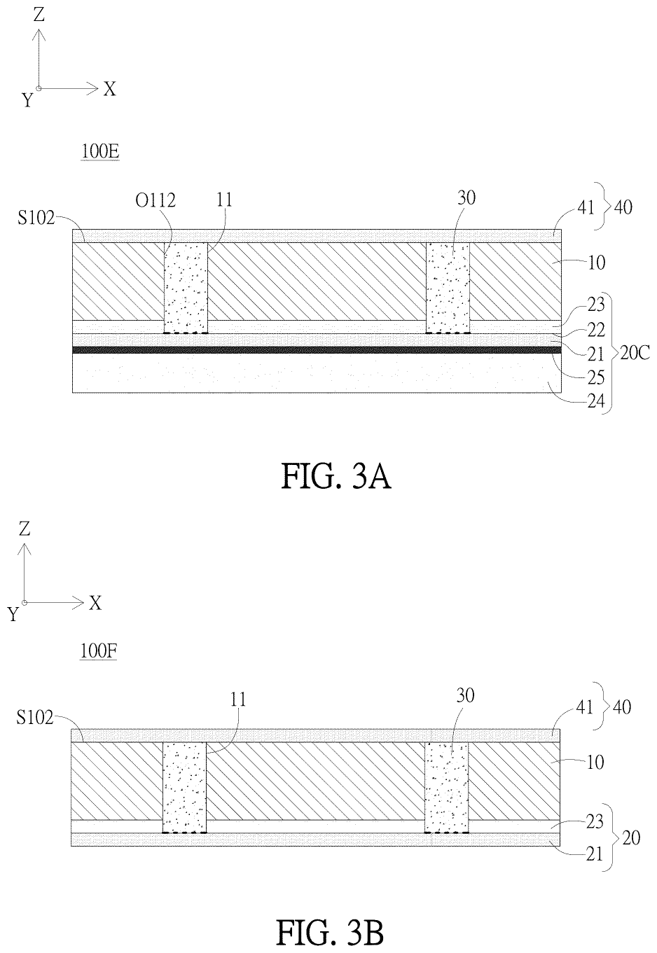

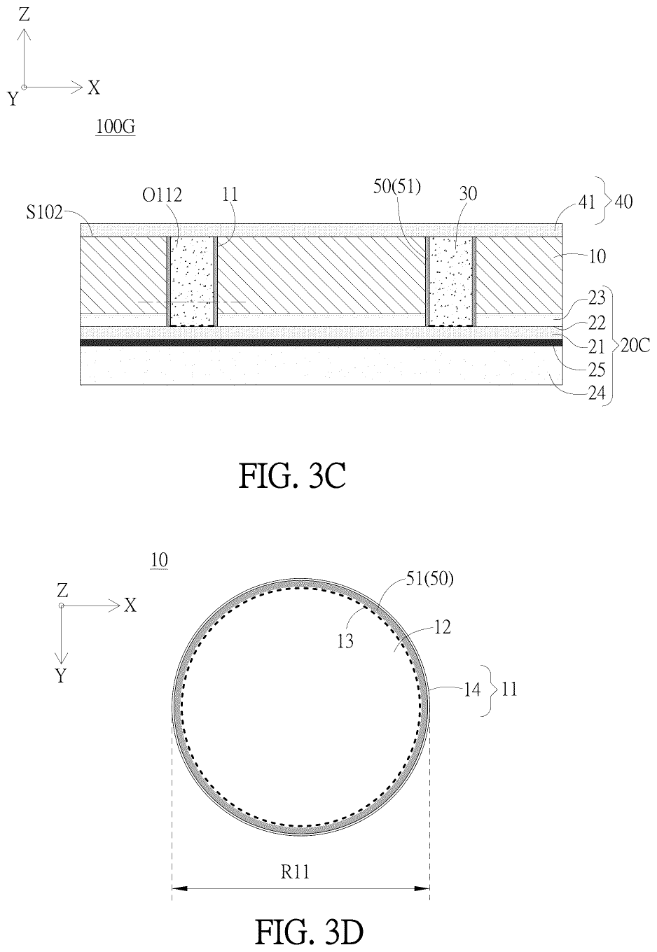

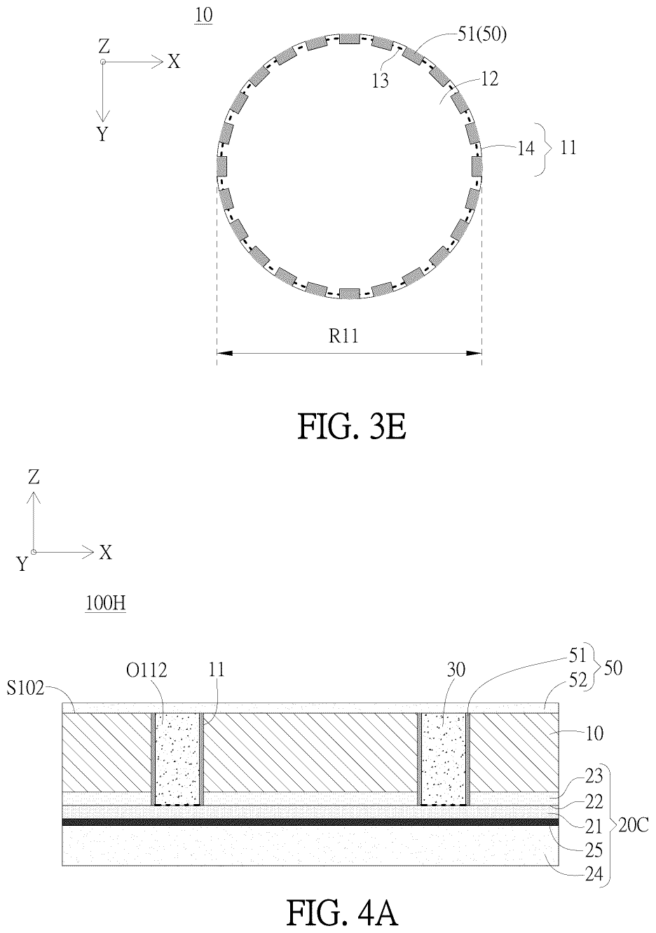

Referring to FIG. 3A, the substrate architecture 100E further includes a second film-layered structure 40. This second film-layered structure 40 is arranged on the opposite side by the surface S102 of substrate 10 and covers at least a partial part the opening O112 of the corresponding one of the through-holes 11 on the other surface of the substrate 10. The second film-layered structure 40 can further fully enclose the opening(s) O112 of the corresponding one of the through-holes 11 on the second surface S102 of the substrate 10. The second film-layered structure 40 comprises at a conductive structure 41 with at least one conductive layer, the conductive structure 41 electrically connects to the corresponding conductive component 30. Referring to 3A, the film-layered structure 20, in this embodiment, comprises the release layer 25, but not limited thereto. Referring to FIG. 3B, the carrier 24 and the release layer 25 in the substrate architecture 100E in FIG. 3A can be removed from the position of the release lay 23 25, to obtain the substrate architecture 100F. The substrate architecture 100F comprises the film-layered structure and the second film-layered structure 40 at the same time. In addition, the substrate architecture 100C in FIG. 2C can be provided with the second film-layered to obtain the substrate architecture 100G as shown in FIG. 3C.

In some embodiments, referring to FIG. 3C, an insulating component 50 is further arranged in the through-hole 11. The insulating component 50 at least includes an insulating material 51, which arranges between the conductive component 30 and the hole wall 14 of the corresponding one of the through-holes 11. The insulating material 51 can serve as a buffer, but not limited thereto. During manufacturing the substrate architecture 3C, the insulating component 50 can be arranged in the through-hole 11 first, and then the second film-layered structure 40 is arranged. Referring to FIG. 3C and FIG. 3D, the insulating material 51 is arranged in a consecutive manner along the hole wall 14, so the insulating material 51 delineates the inner surface 13. In FIG. 3E, the insulating material 51 is arranged discontinuously along the hole wall 14, so the inner surface 13 is jointly delineated by the insulating material 51 and the hole wall 14 The insulating material 51 can be made of or made from different material according to various requirements, the said requirement includes but not limited to buffer or barrier functions. The insulating material 51 can has both functions of buffer and barrier, to prevent interference between two conductive components of adjacent through-holes.

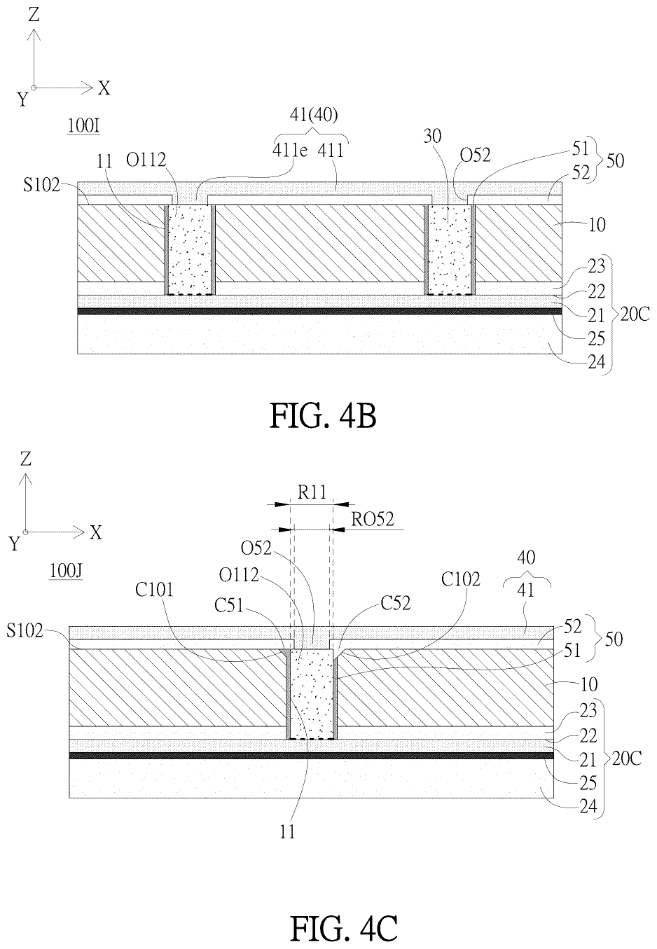

Referring to FIG. 4A, the insulating component 50 of the substrate architecture 100H includes the insulating material 51 and an insulating layer 52. The insulating layer 52 is at least partially arranged on the second surface S102 of the substrate 10. The insulating layer 52 can also be made of or made from different material according to various requirements, the said requirement includes but not limited to buffer, protection, or barrier functions. As shown in FIG. 4A, the insulating layer 52 can be a continuous non-patterned or patterned insulating layer or a patterned insulating layer, to seal the openings O112 of those through-holes 11 at the second surface S102 of the substrate 10; at this point, a substrate architecture 100H can serve as a commercial product.

As shown in FIG. 4B, the insulating layer 52 of the substrate architecture 100I can be a continuous non-patterned or patterned insulating layer, and includes a window O52 corresponding to and communicating with the corresponding through-hole 11. In this embodiment, the conductive structure 41 of the second film-layered structure 40 includes at least one conductive layer 411, and the conductive layer 411 has an extending portion 411e extended therefrom and passing through window O52 to electrically connect with conductive component 30 in the through-hole 11. Here, the conductive layer 411 and extending portion 411e can be made of the same material, and the extending portion 411e can be completed by electroless plating or electroplating, and formed by deposition from conductive component 30, thereby making the conductive layer 411 and the extending portion 411e essentially formed as one piece integrally, but not limited thereto.

Referring to the substrate architecture 100J in FIG. 4C, a diameter RO52 of opening O52 is not larger than a diameter R11 of through-hole 11O, so the insulating layer 52 can protect effectively the corners of the substrate 10 around the opening O112 of through-hole 11. I In this embodiment, the diameter RO52 of opening O52 is smaller than the diameter R11 of through-hole 11, in other words, a projection perpendicular to the substrate 10 the opening O52 covers the through-hole 11O.

In one embodiment as shown in FIG. 4C, the substrate 10 has notches C101, C102 derived at the opening O112 of the corresponding one of the through-holes 11, however, the notches C101, C102 may not exist at the same time. The formation of notches C101, C102 can be either actively designed chamfers structure or a structure formed inevitably during the manufacturing, and the notches C101, C102 may not formed on the same surfaces of the substrate 10. When the insulating material 51 or/and the insulating layer 52 is applied, the notches C101 and C102 can be filled to form the filling members C51 and/or C52.

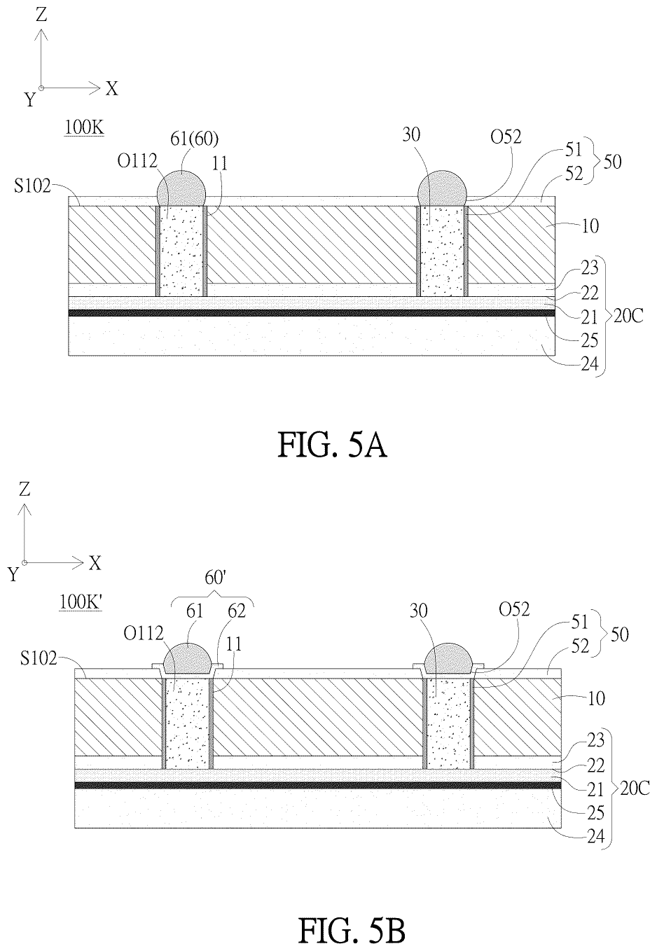

Referring to both FIG. 5A and FIG. 5B, the substrate architecture 100K, 100K′ further includes an external conductive component 60 (60′), arranged on the opposite side of the substrate 10, which is away from the film-layered structure 200, and electrically connecting to the corresponding conductive members 30. The external conductive component 60 in FIG. 5A includes a conductive member 61, which includes but not limited to a conductive ball or conductive bump. The conductive member 61 electrically connecting to the corresponding conductive member 30 through the window O52 of the insulating layer 52 directly. The external conductive member 60′ in FIG. 5B includes a conductive member 61 and a pad member 62 arranged between the conductive element 61 and the corresponding conductive member 30, where this pad member 62 can include but not limited to a thickened pad or an under-bump metallization (UBM). The pad member 62 electrically connecting to the corresponding conductive member 30 through the opening O52 of the insulating layer 52 directly.

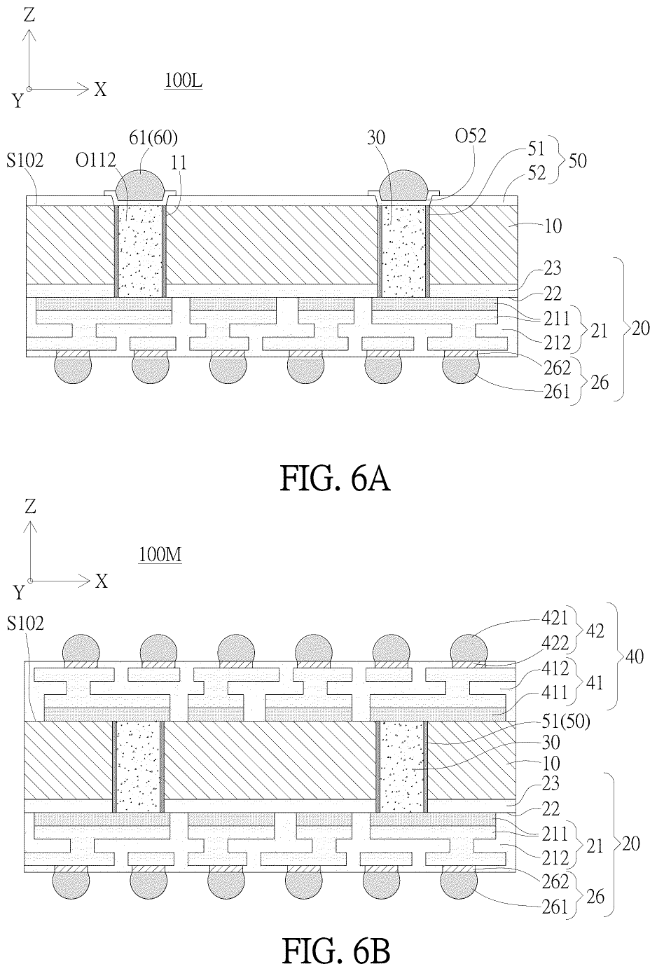

Referring to both FIGS. 6A and 6B, the film-layered structure 20 of the substrate architecture 100L and 100M includes at least a conductive structure 21, the conductive structure 21 comprises multiple patterned conductive layers 211, with at least two of the patterned conductive layers 211 are electrically connected to each other, and these patterned conductive layers 211 are combined with an insulating material 212. In this embodiment, the film-layered structure 20 further includes an adhesive layer 23 connecting the conductive structure 21 and the substrate 10; here, the surface S202 of the film-layered structure 20 is a surface of the adhesive layer 23 facing the substrate 10. In this embodiment, the conductive surface 22 of the film-layered structure 20 is a surface of one of the patterned conductive layers 211 facing the substrate 10. The conductive face 22 can be a metal layer or a seed layer, and the conductive surface 22 is a seed layer in this embodiment. The film-layered structure 20 may further include an external conductive component 26, which electrically connects to the opposite side of the conductive structure 21R away from the substrate 10. In this embodiment, the external conductive component 26 electrically connects to one of the patterned conductive layers 211 away from the substrate 10. The external conductive component 26 includes at least a conductive member 261, which includes but is not limited to a conductive ball or conductive bump. The external conductive component 26 can further includes a pad member 262 arranged between the conductive member 261 and the corresponding patterned conductive layer 211, where this pad member 262 can be but is not limited to a thickened pad, an under-bump metallization (UBM), or a surface finish layer. As shown in FIG. 6B, the substrate architecture 100M comprises an second film-layered structure 40 which has a conductive structure 41, and the conductive structure 41 at least includes one conductive layer 411, the conductive layer 411 electrically connecting to the corresponding conductive member 30. In this embodiment the conductive structure includes multiple conductive layers 411, and the multiple conductive layers 411 are patterned conductive layers, with at least two of the patterned conductive layers 411 electrically connected to each other, and these patterned conductive layers 411 are combined with an insulating material 412. In this embodiment, the second film-layered structure 40 further include an external conductive component 42, which electrically connects to the side of the conductive structure 41 opposite to the substrate 10; here, the external conductive component 42 electrically connects to one of the patterned conductive layers 411 away from the substrate 10. The external conductive component 42 includes at least a conductive member 421, which includes but not limited to a conductive ball or conductive bump. The conductive member 42 can further include a pad member 422 arranged between the conductive member 421 and the corresponding patterned conductive layer 411, where this pad member 422 includes but not limited to, a thickened pad, an under-bump metallization (UBM), or a surface finish layer. The above-mentioned embodiments can be combined with each other in various arrangements and can serve as marketable commercial products.

Additionally, the abovementioned substrate architecture or the film-layered structure may further include one or more optical path(es), thereby enabling optical signal transmission, which may be integration with electrical signal transmission.

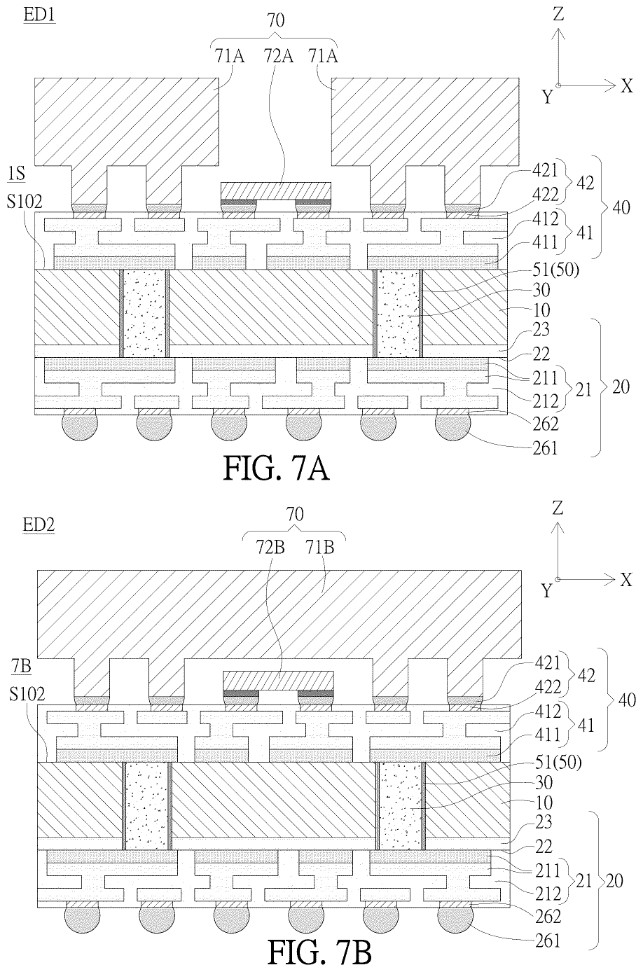

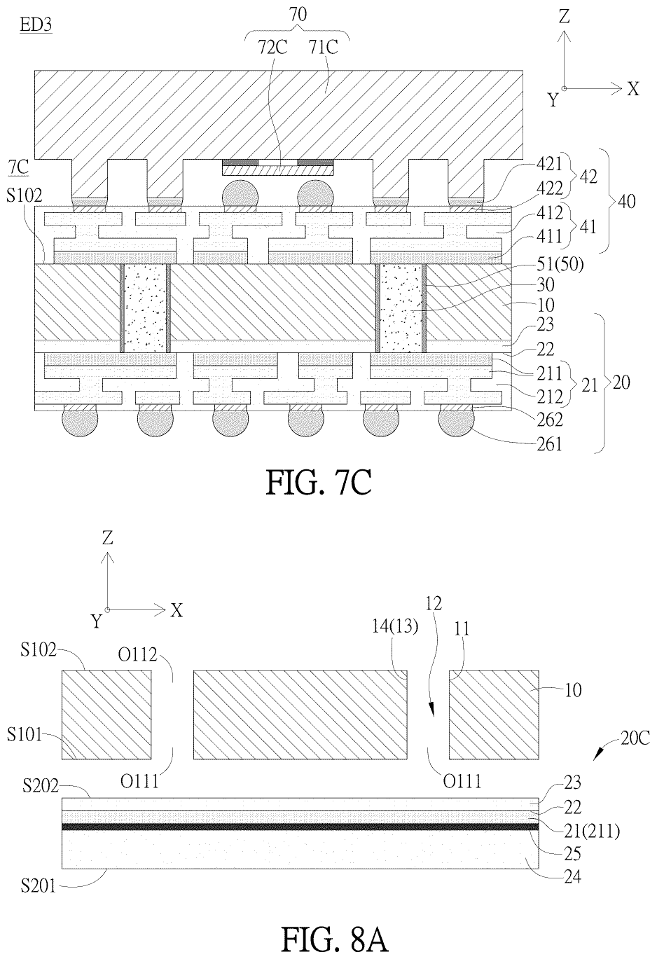

FIGS. 7A, 7B, and 7C disclose an electronic device ED1, ED2, and ED3, which includes but is not limited to an electronic module, a chiplet, or a Chip-on-Wafer-on-Substrate (CoWoS) package, utilizing the above-mentioned substrate architecture, and is applied to different application by the external conductive components. In this embodiment, multiple electronic components 70, 71, 72 are electrically connected to the multiple external conductive components 42 of the second film-layered structure 40, with its. These electronic components 70 can be of the same or different functions/characteristics; for example, integrated circuits (IC), memories, high bandwidth memory (HBM), intelligent power devices (IPD), sensing components, or light emitting diodes (LED), which can be applied in fields such as system integration, supercomputers and AI servers, RF modules, micro electro mechanical systems, co-packaged optics (CPO), power management, and IoT devices. In FIG. 7A, FIG. 7B and FIG. 7C, the electronic device ED1, ED2, and ED3 include electronic components with different functions, and the film-layered structures of the substrate architecture including multiple conductive layers and multiple external conductive structures. As shown in FIG. 7A, in the electronic device ED1, one electronic component 72A is positioned between two adjacent electronic components 71A. As shown in FIG. 7B, in the electronic device ED2, one electronic component 72B is positioned between another electronic component 71B and the substrate architecture 7B, wherein the different electronic components 71B, 72B are directly electrically connect to the substrate architecture 7B. As shown in FIG. 7C, in the electronic device ED3, one electronic component 72C is also positioned between another electronic component 71C and the substrate architecture 7C, but different from FIG. 7B, the electronic component 72C directly electrically connects to the electronic component 71C, and the electronic component 71C directly electrically connects to the substrate architecture 7C; which means that the electronic component 71C is indirectly electrically connected to the substrate architecture 7C through the electronic component 71C. Among these, the electronic component 72B, 72C that can be accommodated between the pins of electronic component 71B, 71C can include but is not limited to, an intelligent power device (IPD) or sensing component, where the sensing component may include a light emitting diode. If the electronic components 71B, 72B have optical communication functions, the substrate architecture of the present invention can further include optical communication paths corresponding to the aforementioned electronic components 71A, 72A, for example, optical waveguide structures or through-hole structures arranged in the substrate and/or its film-layered structure.

The following disclosures are some manufacturing processes for the substrate architecture, which serves only as an example and does not limit the implementation of other processes, nor does it restrict the adoption of additional steps in this process.

A manufacturing method for the substrate architecture according to the present invention includes at least two steps: Step 1: providing a substrate assembly first, which includes a substrate with through-holes and a film-layered structure that covers at least a partial part of the through-holes of the substrate; in this step, the through-holes can be formed in the substrate before the substrate is combined with the film-layered structure, or the substrate is combined with the film-layered structure before forming the through-holes, which is not restricted. Step 2: depositing a conductive material and forming a conductive component in the corresponding one or ones of the through-holes; before, during, or after Step 2, derivative processes required for other purposes may be implemented, and any process that can be combined with the earliest method of this invention is also not restricted.

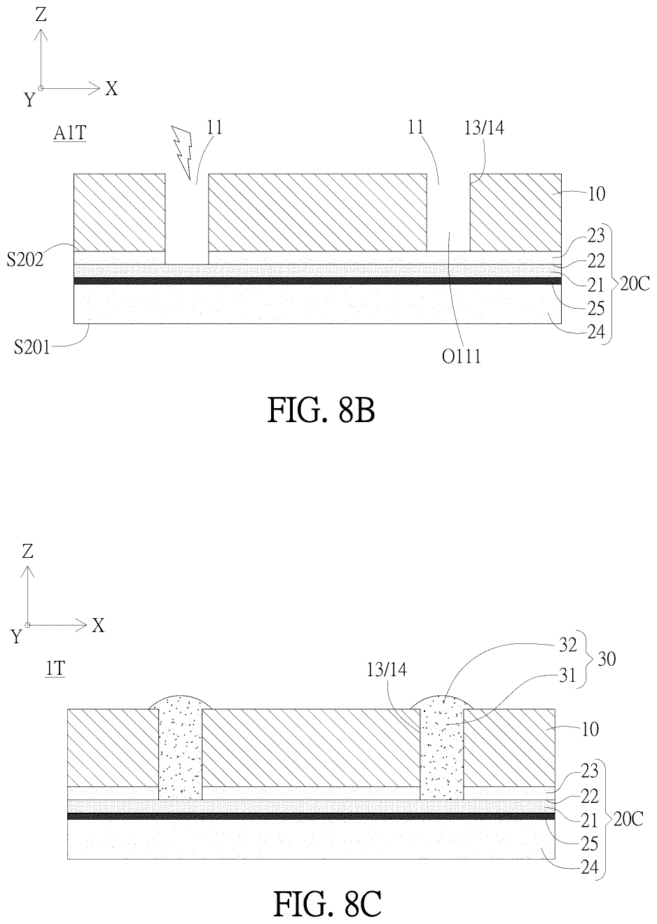

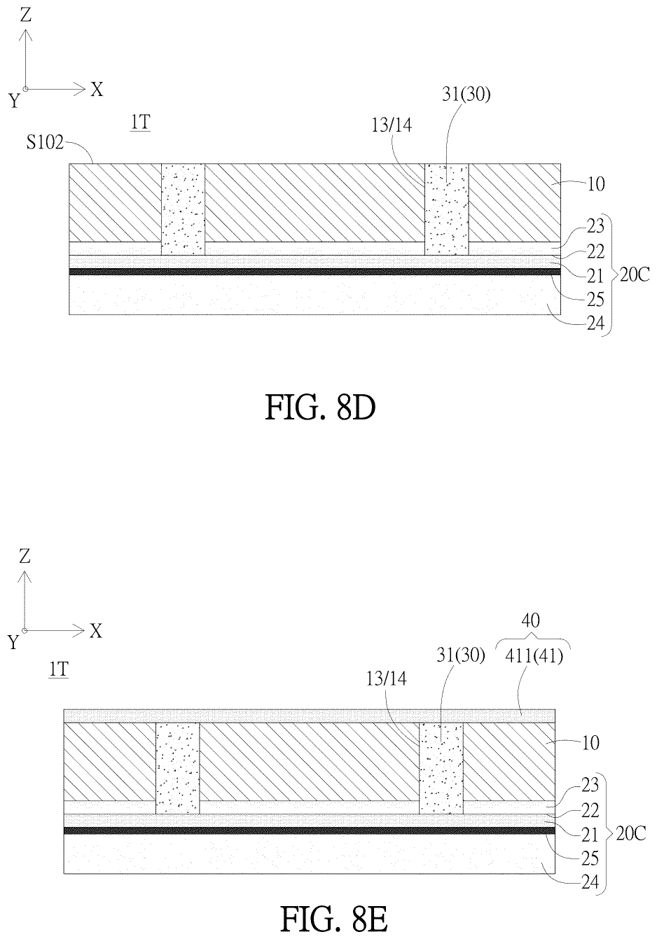

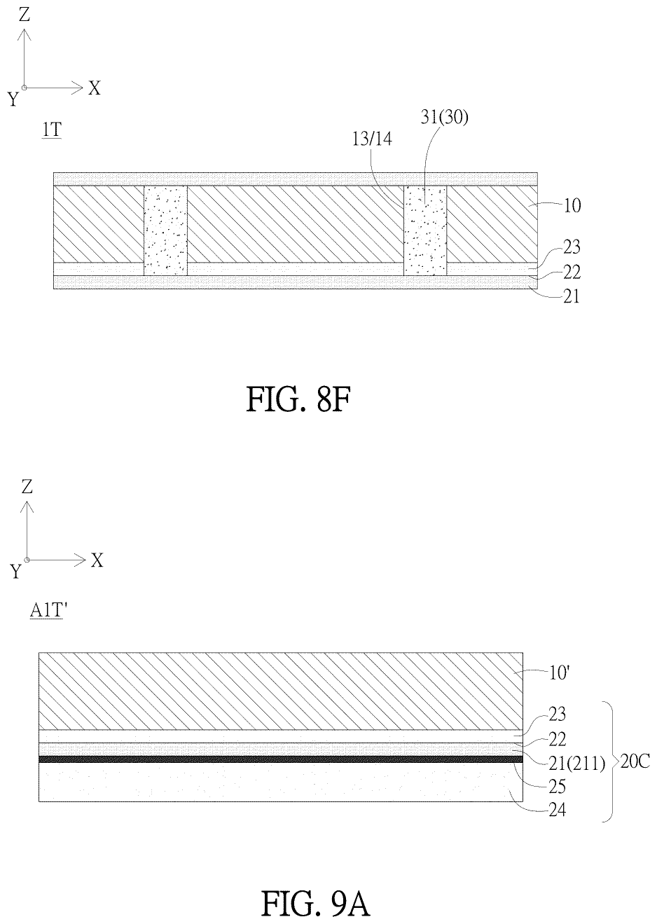

Referring to FIGS. 8A to 8F, one manufacturing method for the substrate architecture is disclosed. FIG. 8A is a schematic diagram to preparation the substrate assembly A1T shown in FIG. 8B. The substrate assembly A1T comprises a substrate 10 having a plurality of through-holes 11, each through-hole 11 defined by a hole wall 14 and the hole wall 14 is the inner surface 13 at this stage. The inner surface 13 delineates an accommodation space 12. The substrate 10 and film-layered structure 20 are brought together, with the film-layered structure 20 covers at least a partial part of an opening O111 at one end of the corresponding one of the through-holes 11 in the substrate 10. The film-layered structure 20 includes a conductive structure 21, an adhesive layer 23 connected to one side of the conductive structure 21 and facing the substrate 10, a carrier 24 on the other side of the conductive structure 21, and a release layer 25 jointing the conductive structure 21 and the carrier 24, but is not limited thereto. The film-layered structure 20 defines two opposite surfaces S202 and S201, the film-layered structure faces to the substrate by the surface S202. At this point, the through-holes 11 expose the surface S202 of the film-layered structure 20. Referring to FIG. 8B, after preparing the substrate assembly A1T, laser or plasma technology can be used to clean the through-holes 11 and to clean the corresponding areas of the adhesive layer 23, and exposing the conductive structure 21, especially exposing a conductive face 22 that is at least partially conductive of the conductive structure 21 by the through-holes 11 to reveal. The laser technology is shown in FIG. 8B, bit is not limited thereto. Referring to FIG. 3C, an electroplating process is performed to gradually deposit conductive material between the conductive face 22 (which is considered as a cathode) of the film-layered structure 20 and the electroplating electrode (which is considered as a anode). The conductive material is deposited from the bottom of the through-hole 11 (other than from the hole wall 14), thereby forming the conductive component 30, and obtaining the substrate architecture 1T. The conductive component 30 may include at least a conductive segment 31, and a conductive protrusion 32 extend from the conductive segment 31 and protruded out of the substrate 10. However, in some embodiments, as shown in FIG. 8D, the substrate architecture 1T does not include the conductive protrusion 32 in this stage. Since the conductive component 30 is deposited from the bottom of the through-hole 11, it is deposited along a direction Z perpendicular to the substrate 10, other than growing radially from the hole wall 14 of the through-hole 11 in a second direction Y parallel to the substrate 10, the contact between the conductive component 30 and through-hole 11, especially the inner surface of the through hole is by a non-chemical bonding status, which is reversible, and the conductive components 30 cab be easily separated, removed or peeled off from the inner surface 13 of the through-hole 11. Therefore, stress generated during thermal expansion and contraction does not transfer to the inner surface 13 of the corresponding one of the through-holes 11, so as to reduce or avoid potential risks such as substrate 10 deformation, micro cracking, damage, warping, or material fatigue. Referring to FIG. 8D, a removal processes is further performed such as grinding and/or polishing, or the process having similar effects to remove the conductive protrusion 32, and aligning the conductive component 30 on the side of opening O112 with the second surface S102 of substrate 10. Referring to FIG. 8E, the second film-layered structure 40 is provided on the second surface S102 of the substrate 10 in the substrate architecture 1T, to cover at least a partial part of the opposite opening O112 of the through-hole 11. The second film-layered structure 40 includes a conductive structure 41, and the conductive structure includes a conductive layer 411, the conductive layer can be formed by vacuum sputtering, vacuum evaporation, magnetron sputtering, electroplating, chemical plating, chemical vapor deposition, printing technology, or ion beam assisted deposition. The conductive layer 411 can be patterned or non-patterned conductive layer, and can be either a conductive layer with signal transmission or a seed layer for subsequent formation of a conductive layer with signal transmission thereon. Referring to FIG. 8F, provides light exposure or temperature change to the release layer 25 of the film-layered structure 20 of the substrate architecture 1T to remove the release layer 25 and carrier 24 from the conductive structure.

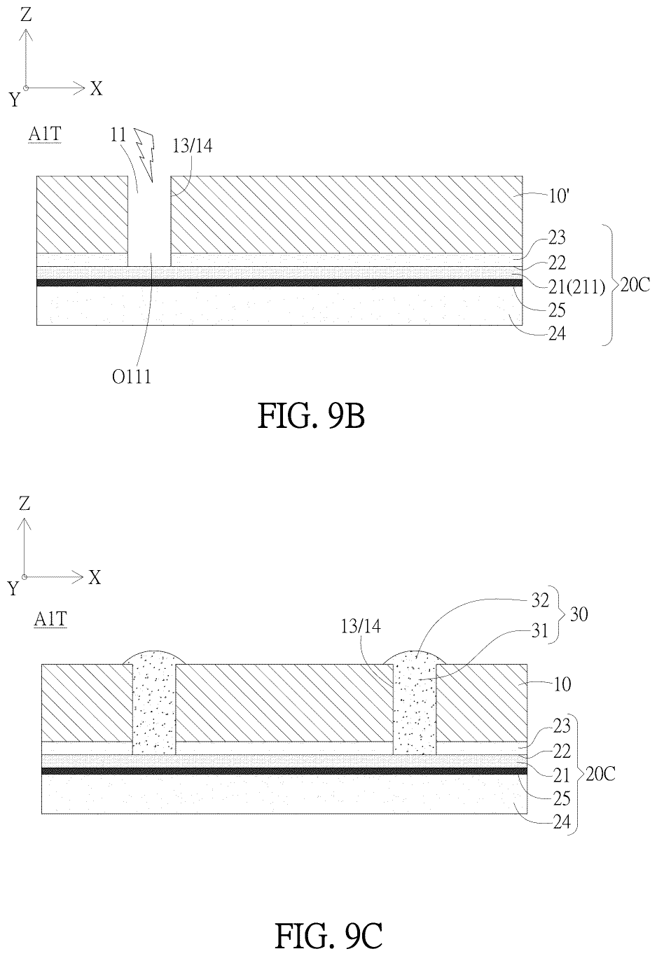

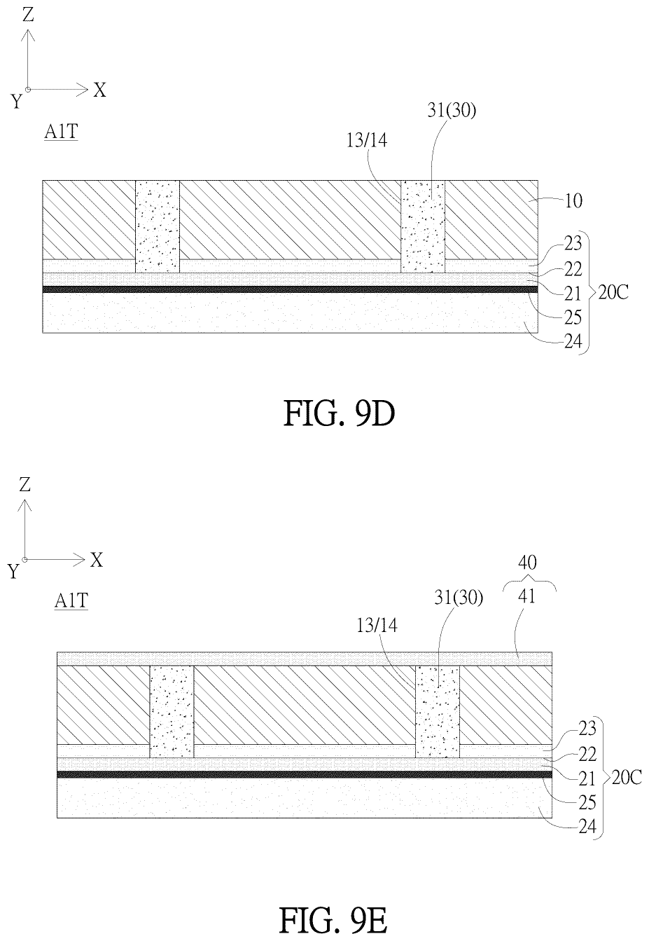

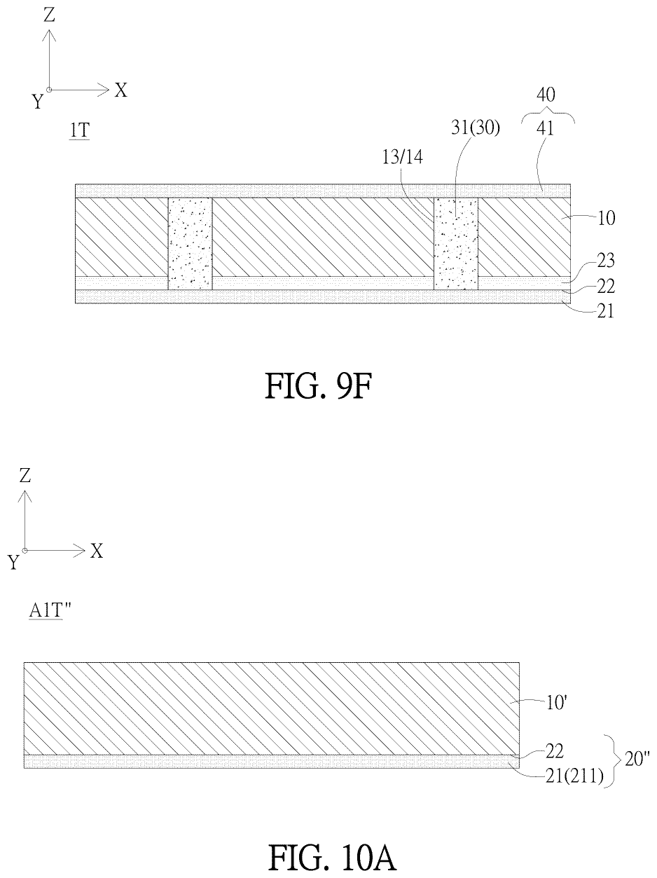

The substrate assembly A1T shown in FIG. 8B can also manufactured by the method shown in FIG. 9A and FIG. 9B. As shown in FIG. 9A, the film-layered structure 20 is first bond to an undefined substrate 10′to form the substrate assembly A1T′; here, “undefined” means at least no through-holes 11 have been formed yet. The film-layered structure 20 in this embodiment at least includes a conductive structure 21 comprising a conductive layer 211, and the film-layered structure 21 can further include an adhesive layer 23, a carrier 24, and a release layer 25, but not limited thereto. After bonding the substrate 10 with the film-layered structure 20, multiple through-holes 11 are then formed in the substrate 10, for example, through laser drilling. The other opening O111 of the through-hole 11 is stop at the conductive structure 21 (conductive layer 211) to expose the conductive surface 22. In addition, the step of forming the through-hole 11 may proceed as: modification of substrate 10′ may by laser process, then perform an etching process thereafter to form the through hole in the substrate 10′. In some embodiments, the adhesive layer 23 can be arranged on the substrate 10′ first, and then bond with a laminated structure of the conductive structure 21—the release layer 25—the carrier 24 to obtain the substrate assembly A1T′ as shown in FIG. 9A. After forming the through-holes 11 in the substrate 10′, the electroplating process abovementioned is preformed to deposit the conductive material in the through-holes and form the conductive components 30, as shown in FIG. 9C and FIG. 9D. Additionally, as shown in FIG, 9E and FIG. 9F, a second film-layered structure 40 is arranged to the side of the substrate assembly a1T opposite to the film-layered structure 20, and the release layer 25 and the carrier 24 of the film-layered structure 20 is removed to form the substrate architecture 1T.

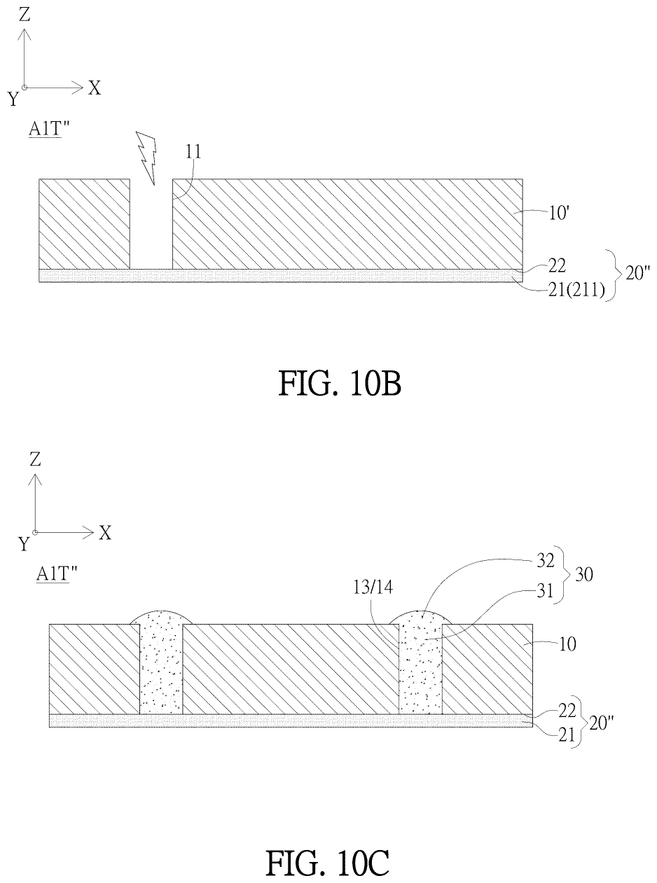

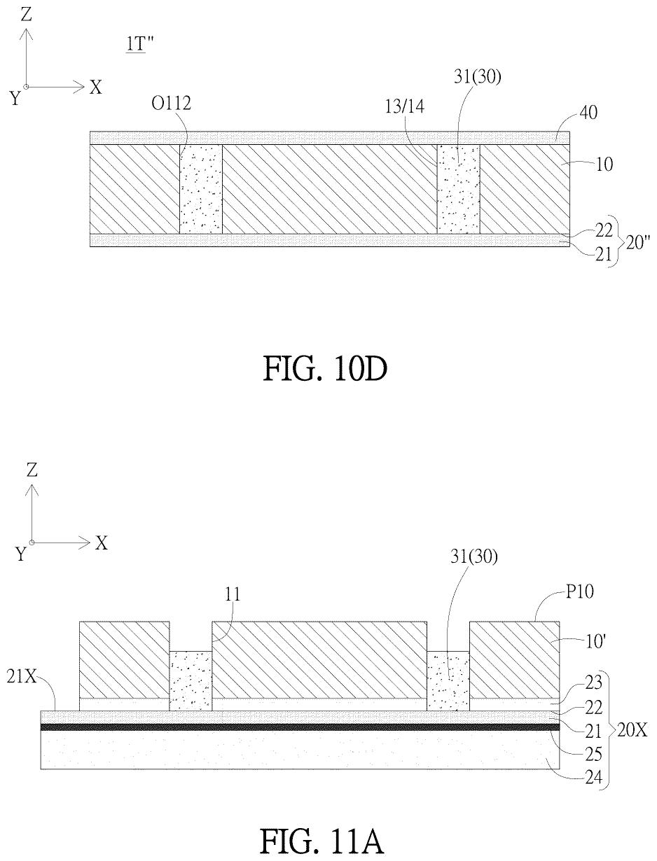

Referring to FIG. 10A, in another manufacturing method, the conductive layer 211 is first formed on the undefined substrate 10′by techniques such as stress lamination or hot-pressing of metal foil, gradual plating of metal seed layer, or electroplating of metal layer to form the substrate assembly A1T″. The substrate assembly A1T″ does not include the adhesive layer, the release layer 25 and the carrier 24 compare to the substrate assembly A1T′ in FIG. 9A. The film-layered structure 20″ may only include the conductive structure 21, the conductive layer 211 of the conductive structure 21 and the conductive surface 22. In FIG. 10B, forming a plurality of through-holes in the substrate 10′ of the substrate assembly A1T″. In this embodiment, the conductive layer 211 of the conductive structure 21 can be a patterned conductive layer or a non-patterned conductive layer, and the conductive layer 211 in this embodiment can also a multi-layer conductive layer (can be referred to FIG. 6A), but is not limited thereto. Then, as shown in FIG. 10C and FIG. 10D, the conductive component 30 is deposited in the through-hole 11 by the abovementioned electroplating process, and the second film-layered structure 40 can be also arranged thereto, but is not limited.

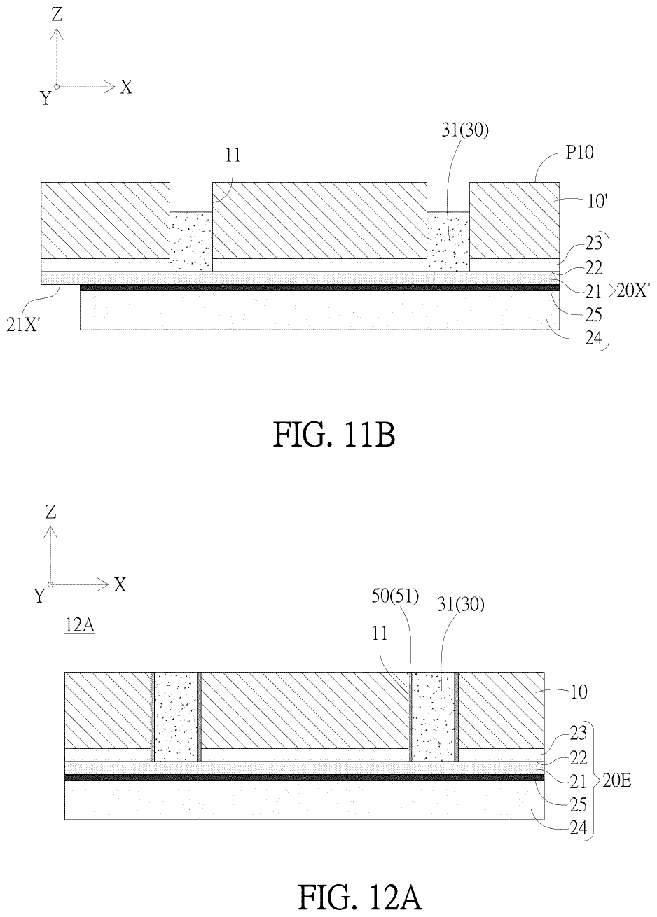

To enhance the convenience or efficiency of the electroplating process, referring to FIG. 11A, a projection of the substrate 10′ in a direction X perpendicular to the substrate 10′ is not the same as the projection of the film-layered structure 20X. The film-layered structure 20X, especially the conductive layer 211 of the film-layered structure 20X, can protrude beyond the substrate 10′in the direction X parallel to the horizontal plane P10 resulting in partial part of the conductive layer 211 of the conductive structure 21 is not covered by the substrate 10′ to expose a conductive portion 21X. The conductive portion 21X can be a part of the conductive face 22. This relative positioning can improve the efficiency of power feeding to the conductive layer 211 of the conductive structure 21. Alternatively, as shown in FIG. 11B, the carrier 24 of the film-layered structure 20X′ may be recessed along the direction X parallel to the horizontal plane P10 of substrate 10′, so the projection of the conductive layer of the conductive structure 21 in the direction Z perpendicular to the horizontal plane P10 is recessed relative to the substrate 10′, in which a exposed conductive portion 21X′ of the conductive layer 211 is also formed.

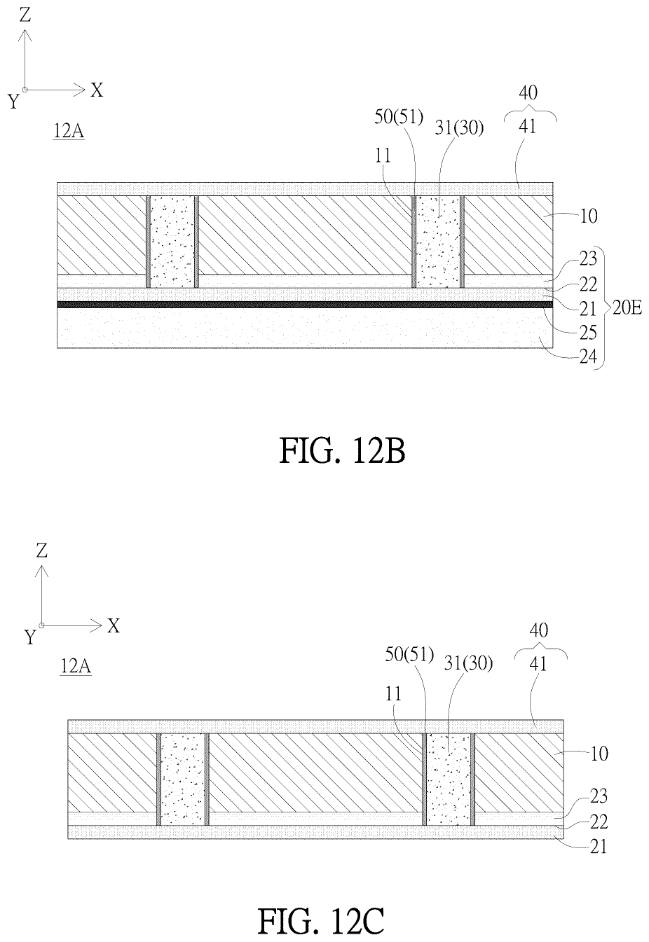

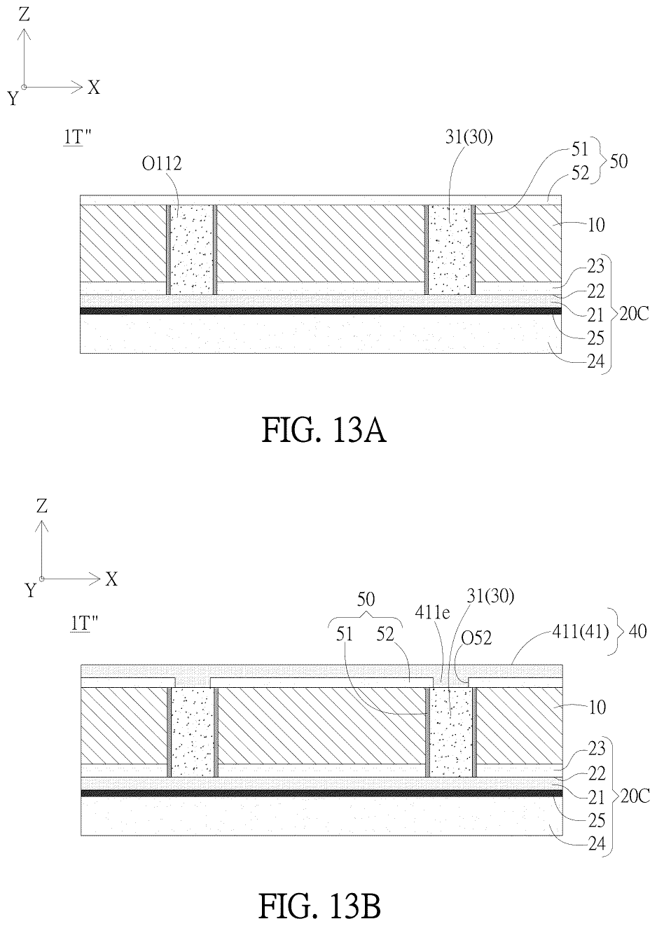

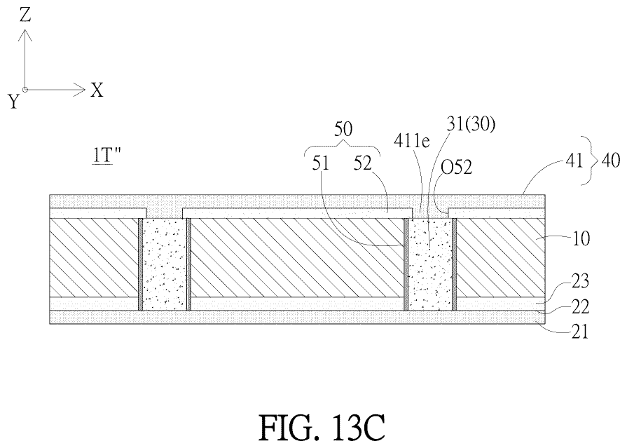

Referring to FIG. 12A, an insulating component 50, for example an insulating material, can be arranged to the hole wall 14 of the through-hole 11 after forming the through-holes 11 in the substrate assembly A1T in FIG. 8B, and before deposition of the conductive material The insulating material 51 can a buffer layer formed on the hole wall 14, or an oxidized metal layer or a barrier layer. In addition, the through-hole 11 can be filled with insulating material and then forming an inner hole, then deposition of conductive material in the through-hole 11(or in the inner hole) to obtain the substrate architecture in FIG. 12A. As shown in FIG. 12B second film-layered structure 40 can be arranged on the substrate architecture shown in FIG. 12A. The release layer 25 and the carrier can be further removed as shown in FIG. 12C. In another embodiment as shown in FIG. 13A, the substrate architecture 12A in FIG. 12A includes an insulating layer 52 at the side of the substrate 10 opposite to the film-layered structure 20. The insulating layer 52 covers at least a partial part of the second surface S102 of the substrate 10. The functions of the insulating layer 52 are described in the previous section. The insulating layer 52 can be either a continuous non-patterned or patterned insulating layer, and covers the openings O112 of the through-holes 11. Then, one or more windows O52 are formed at the position corresponding to the through-holes 11 of the substrate 11. The second film-layered structure 40 is then arranged on the insulating layer 52, as shown in FIG. 13B. The description of this structure can be seen with reference to the description of FIG. 4B. At last, as shown in FIG. 13C, the release layer 25 and the carrier 24 of the film-layered structure are removed.

Based on the above description, it should be understood that various embodiments of the present invention have been described in the specification for illustrative purposes, and various modifications can be made without departing from the scope and spirit of the present invention. Therefore, the various embodiments of the present invention are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A substrate architecture comprising:
a substrate, defining a first surface, a second surface opposite to the first surface, a plurality of through-holes; wherein each of the through-holes is defined with an accommodation space and an inner surface defining the accommodation space, and two openings respectively arranged on the first surface and the second surface;
a film-layered structure arranged on at least one of the first surface or the second surface of the substrate, and covering at least partial of an opening of a corresponding one of the through-holes; wherein the film-layered structure defines a conductive surface facing the opening of the through-hole, and where the conductive surface corresponding with the opening is at least partially conductive; and
a plurality of conductive components, respectively arranged in the accommodation space of the through-holes, at least partially of the conductive components contacting the inner surfaces of the corresponding ones of the through-holes, and electrically connecting to the conductive surface of the film-layered structure;
wherein one of the conductive components defines a cross-sectional profile of a homogeneous medium in a direction along a horizontal plane of the substrate.

2. The substrate architecture as claimed in claim 1, wherein the substrate comprises at least one of a glass material, a ceramic material, or a glass-ceramic material.

3. The substrate architecture as claimed in claim 1, wherein the substrate is a multi-layer substrate and at least one layer of the multi-layer substrate comprises an organic material, and the layer comprising the organic material defines a thickness less than 100 μm.

4. The substrate architecture as claimed in claim 1, wherein the substrate further defines a coefficient of thermal expansion (CTE) along the horizontal plane of the substrate is no greater than 10 ppm/° C.

5. The substrate architecture as claimed in claim 1, wherein the through-hole defines a hole diameter, the substrate defines a substrate thickness, and the ratio of the substrate thickness to the hole diameter is no less than 1.

6. The substrate architecture as claimed in claim 1, wherein the film-layered structure includes a conductive structure.

7. The substrate architecture as claimed in claim 1, wherein the film-layered structure further includes an adhesive layer for bonding the conductive structure to the substrate.

8. The substrate architecture as claimed in claim 1, wherein at least partial of the conductive components contact the inner surfaces of the corresponding through-holes by non-chemical bonding.

9. The substrate architecture as claimed in claim 1, wherein the conductive component is a single conductive-material member.

10. The substrate architecture as claimed in claim 9, wherein the conductive component includes copper material.

11. The substrate architecture as claimed in claim 1, wherein the conductive components is a deposited conductive-material member.

12. The substrate architecture as claimed in claim 1, wherein the conductive components is formed in the corresponding through-hole by an electroplating process utilizing the conductive face of the film-layered structure.

13. The substrate architecture as claimed in claim 1, wherein the through-hole defines an accommodation volume of the accommodation space, the conductive components arranged in the accommodation space of the corresponding through-hole defines a filling volume; the filling volume is not less than 90% of the accommodation volume.

14. The substrate architecture as claimed in claim 1, further including an insulating component; wherein the insulating component includes an insulating material arranged between a hole wall of one of the through-holes and the conductive component arranged therein; wherein the insulating material defines the inner surface of the through-hole, or the insulating material and the hole wall jointly defined the inner surface of the through-hole.

15. The substrate architecture as claimed in claim 1, further including a second film-layered structure on one surface of the substrate opposite to the film-layered structure, the second film-layered structure covers at least partially of an opposite opening of the corresponding one of the through-holes and electrically connect to the corresponding conductive components.

16. The substrate architecture as claimed in claim 15, wherein the second film-layered structure includes a conductive structure.

17. An electronic device, comprising:
a substrate architecture as claimed of claim 1;
a plurality of external conductive components connected to the film-layered structure; wherein the film-layered structure is arranged between the external conductive components and the conductive components, the external conductive components are respectively electrically connected to the conductive components; and
a plurality of electronic components electrically connected to the external conductive components.

18. The electronic device as claimed in claim 17, wherein one of the electronic components is arranged between another one of the electronic components and the substrate architecture.

19. The electronic device as claimed in claim 17, wherein one of the electronic components is located between adjacent two of the electronic components.

20. The electronic device as claimed in claim 17, wherein one of the electronic components is an Integrated Passive Device (IPD) or (Light Emitting Diode) LED.
